(19) United States
(12) Patent Application Publication
(10) Pub. No.: US 2006/0220054 A1
(43) Pub. Date: Oct. 5, 2006

(54) SUPER LIGHT FULL SPACE EMITTING DIODE BULED

(75) Inventor: Dimitar Mihailov Prodanov, Montreal (CA)

Correspondence Address: Mr.Dimitar Mihailov Prodanov;7090, boul.Monk, app.14, Montreal, H4E3J3, CA

(73) Assignee: LAURIN PUBLISHING, Pittsfield, MA (US)

(21) Appl. No.: 10/907,405

(22) Filed: Mar. 31, 2005

(51) Int. Cl. H01L 29/24

(52) U.S. Cl. 257/100

(57) ABSTRACT

Certain aspects of the invention may be found in an SLED with an improved luminance dispersion diagram. In one embodiment of the invention, an SLED may include a light-emitting element of solid geometry comprising a p-n junction. The light emitting element of solid geometry may enable distribution of light energy that is multidirectional. The light-emitting element may emit light from substantially its entire surface. The SLED may further include at least one pair of electrodes for coupling the light-emitting element of solid geometry to a source of electricity. The SLED may further include a lens of solid geometry enclosing the light-emitting element and at least a portion of the at least one pair of electrodes. The light-emitting element of solid geometry may include a sphere and/or a cube. The p-n junction may include at least one semiconductor layer disposed on a surface of the light-emitting element of solid geometry.

### CROSS-REFERENCE TO RELATED APPLICATIONS/INCORPORATION BY REFERENCE

[Not Applicable]

### FEDERALLY SPONSORED RESEARCH OR DEVELOPMENT

[Not Applicable]

### MICROFICHE/COPYRIGHT REFERENCE

[Not Applicable]

### FIELD OF THE INVENTION

Certain embodiments of the invention relate to light-emitting diodes. More specifically, certain embodiments of the invention relate to a super luminance light-emitting diode (SLED).

### BACKGROUND OF THE INVENTION

Conventional light-emitting diodes (LEDs) are manufactured according to various industry standards for light emission. For example, LEDs may generate luminance with varying levels of intensity. In addition, LEDs may be adapted to operate at various outside temperatures, such as −45° to 85° C. However, one of the important characteristics of conventional LEDs is the diagram of dispersion of light or luminance. The dispersion characteristics may depend on different factors, such as the mechanic construction of the LED frame, absence or presence of lens, optic characteristics of the frame or the lens, etc. However, a common flaw in conventional LEDs and super luminance light-emitting diodes (SLEDs) is that the light dispersion of the diode is substantially limited.

Further limitations and disadvantages of conventional and traditional approaches will become apparent to one of skill in the art, through comparison of such systems with the present invention as set forth in the remainder of the present application with reference to the drawings.

### BRIEF SUMMARY OF THE INVENTION

A super luminance light-emitting diode (SLED), substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 illustrates a first sectional view of a conventional SLED, which may be used in accordance with an embodiment of the invention.

FIG. 2 illustrates a second sectional view of a conventional SLED, which may be used in accordance with an embodiment of the invention.

FIG. 3 illustrates a luminance dispersion diagram of a conventional SLED, which may be used in accordance with an embodiment of the invention.

FIG. 4 illustrates an SLED with an improved luminance dispersion diagram, in accordance with an embodiment of the invention.

### DETAILED DESCRIPTION OF THE INVENTION

Certain aspects of the invention may be found in an SLED with an improved luminance dispersion diagram. In one embodiment of the invention, an SLED may comprise a light-emitting element of solid geometry comprising a p-n junction. The light emitting element of solid geometry may enable distribution of light energy that is multidirectional. The SLED may further comprise at least one pair of electrodes for coupling the light-emitting element of solid geometry to a source of electricity. The light-emitting element may emit light from substantially its entire surface. The SLED may further comprise a lens of solid geometry enclosing the light-emitting element and at least a portion of the at least one pair of electrodes. The light-emitting element of solid geometry may comprise a sphere and/or a cube. The p-n junction may comprise at least one semiconductor layer disposed on a surface of the light-emitting element of solid geometry. The p-n junction comprises at least one semiconductor layer disposed within a body of the light-emitting element of solid geometry. The lens may comprise an outer surface external to the light-emitting element and an inner surface proximate to the light-emitting element. The lens may comprise a filter that filters the distributed light energy. The filter may be disposed on the outer surface and/or on the inner surface of the lens. The lens may be adapted to magnify the multidirectional light energy distributed by the light emitting element.

In another embodiment of the invention, an SLED may comprise a plurality of light-emitting elements of solid geometry. Each of the plurality of light-emitting elements of solid geometry may comprise a p-n junction. At least a first of the plurality of light-emitting elements may be operatively coupled to at least a second of the plurality of light-emitting elements. The SLED may further comprise a single pair of electrodes for coupling the plurality of light-emitting elements of solid geometry to a source of electricity. The SLED may further comprise a lens of solid geometry enclosing the plurality of light-emitting elements and at least a portion of the single pair of electrodes. The SLED may also comprise at least one pair of electrodes for coupling the plurality of light-emitting elements of solid geometry to a source of electricity. The SLED may further comprise a lens of solid geometry enclosing the plurality of light-emitting elements and at least a portion of the at least one pair of electrodes.

Each of the plurality of light emitting elements of solid geometry may enable distribution of light energy that is multidirectional. Each of the plurality of light-emitting elements may comprise a body that is of spherical or cubical shape. The p-n junction for each of the plurality of light-emitting elements comprises at least one semiconductor layer disposed on a surface of the each of the plurality of light-emitting elements of solid geometry. The p-n junction for each of the plurality of light-emitting elements may comprise at least one semiconductor layer disposed within a body of the each of the plurality of light-emitting elements of solid geometry. The lens may comprise a filter that filters the distributed light energy. The filter may be disposed on an outer surface of the lens and/or on an inner surface of the lens. The lens may magnify the multidirectional light energy distributed by the plurality of light emitting elements.

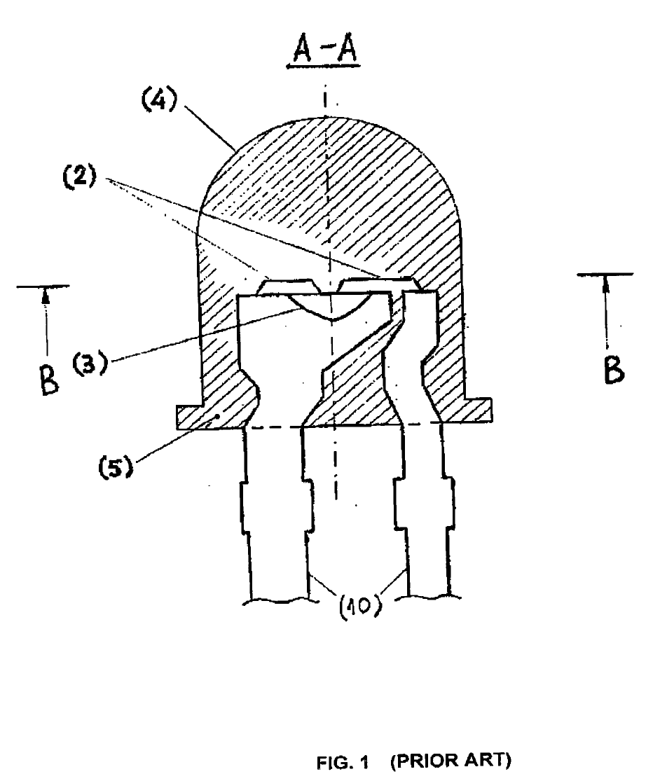

FIG. 1 illustrates a first sectional view of a conventional SLED, which may be used in accordance with an embodiment of the invention. Referring to FIG. 1, the conventional SLED illustrated therein may comprise a p-n semiconductor pit 3, a pair of electrodes 10, conductors 2, lens 4, and transparent epoxy filling the inside of the lens 4.

During operation, the conventional SLED may generate luminance or light. However, the generated light will be more intense at or near the upper rounded portion of lens 4, and less intense in the lower portion of the lens 4. Furthermore, no light may be emitted at the bottom portion of the lens 4, towards the pair of electrodes 10. In this regard, conventional SLEDs are characterized by non-uniform and unidirectional light dispersion, which decreases the overall efficiency and desirability of the conventional SLED.

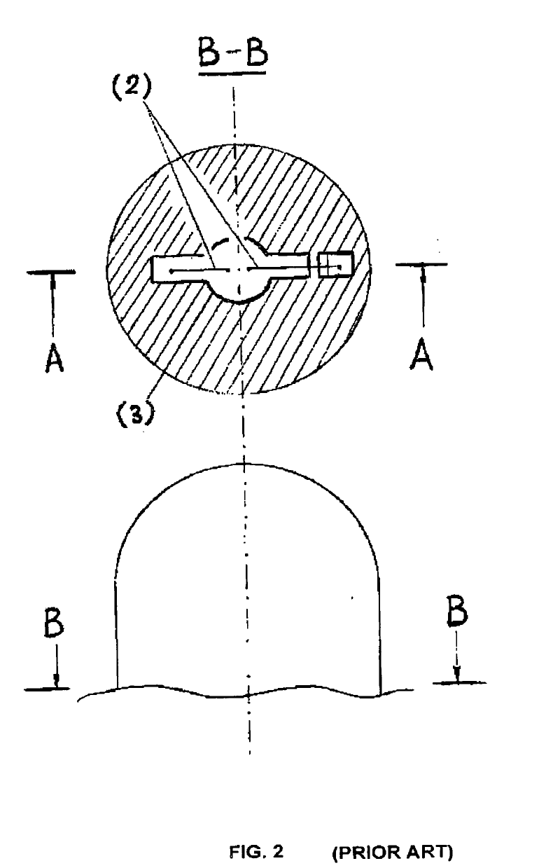

FIG. 2 illustrates a second sectional view of a conventional SLED, which may be used in accordance with an embodiment of the invention.

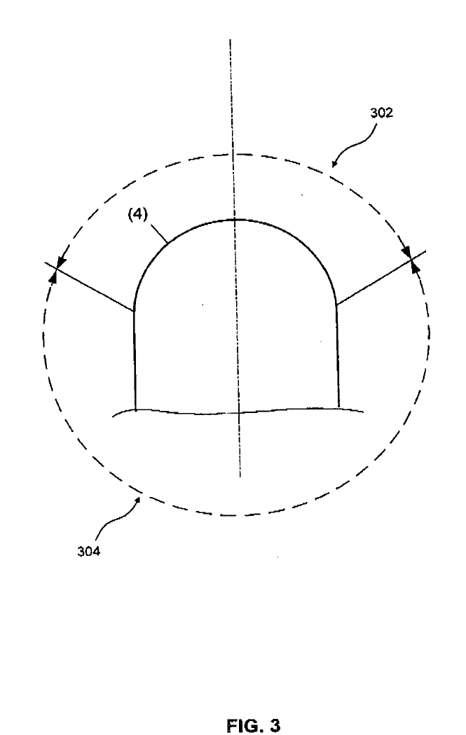

FIG. 3 illustrates a luminance dispersion diagram of a conventional SLED, which may be used in accordance with an embodiment of the invention. Referring to FIG. 3, a partial sectional view of a conventional SLED, such as the SLED of FIGS. 1 and 2, is illustrated. During operation, the conventional SLED may generate luminance or light. However, the generated light will be more intense at or near the upper rounded portion of lens 4. For example, the generated light will be characterized with increased intensity in or near section 302. Within a two-dimensional sectional view of lens 4, section 302 may measure about 110 degrees. In this regard, section 302 may represent a reduced conical sector of space with increased luminance intensity. Similarly, generated light may be diffused and may be less intense in the lower portion of the lens 4, namely, within sector 304. Within a two-dimensional sectional view of lens 4, section 304 may measure about 260 degrees. In this regard, section 304 may represent a reduced conical sector of space with reduced luminance intensity.

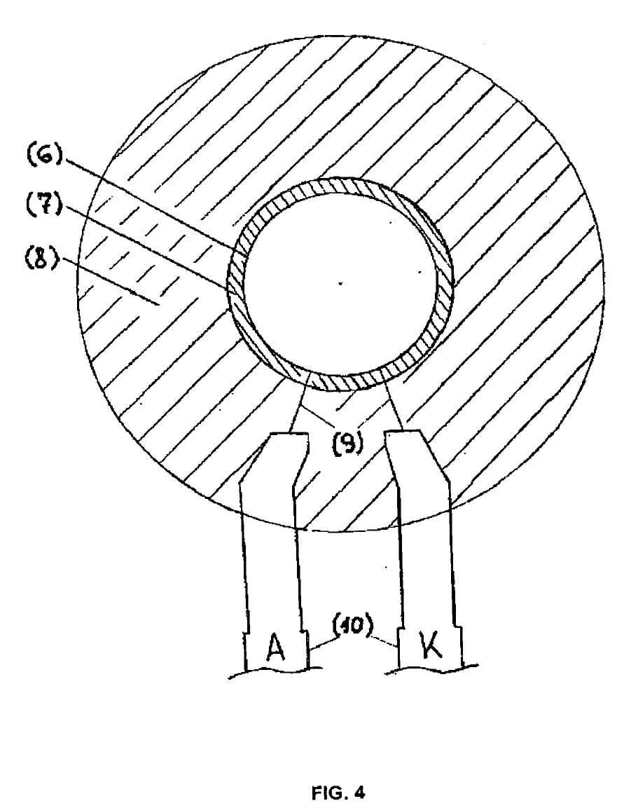

FIG. 4 illustrates an SLED with an improved luminance dispersion diagram, in accordance with an embodiment of the invention. Referring to FIG. 4, the SLED illustrated therein may comprise a body or frame 6, which may be of spherical shape. The SLED may further comprise a semiconductor layer 7, which may comprise a p-n junction, lens B, micro-conductors 9, and a pair of electrodes 10. The semiconductor layer 7 may be disposed on the surface of the spherical body 6. In an alternative embodiment, the semiconductor layer 7 may be disposed within at least a portion of the body 6. The semiconductor layer 7 may be disposed on the body 6 using nanocrystal technology, for example. Such technology may result in a semiconductor layer 7 with a thickness of around 2 nm to about 300 nm, for example. In another embodiment of the invention, the body 6 may comprise a shape other than sphere, such as a cube, for example.

In yet another embodiment of the invention, the body or frame 6 may comprise semiconductor material, which may be utilized during a process of electro-luminance and during luminance generation by the SLED when electrodes 10 are connected to electricity. In this regard, the micro-conductors 9 may be directly connected to the body 6, without the use of the layer 7. In yet another embodiment of the invention, the body or frame 6 may comprise semiconductor material, which may be utilized during a process of electro-luminance (a process of generating light with the use of electricity) and during luminance generation by the SLED when electrodes 10 are connected to electricity. In this regard, the micro-conductors 9 may be directly connected to the body 6, without the use of the layer 7. In such instances, when the body 6 is connected to electricity via the electrodes 10 and the conductors 9, the body 6 may generate light in substantially all directions around the lens 8.

In another embodiment of the invention, the body or frame 6 may comprise non-semiconductor material, such as sapphire or ceramics, for example. In another embodiment of the invention, the inside surface or the outside surface of the lens 8 may be coated so that the color of the generated light may be changed. Furthermore, the lens 8 may comprise a filter that may filter all or a portion of the luminance generated by the semiconductor layer 7.

The SLED illustrated in FIG. 4 may utilize electro-luminance injection. However, rather than utilizing a semiconductor layer disposed on a flat or substantially flat surface, the SLED in accordance with the present invention utilizes a body or a frame of solid geometry, such as a sphere or a cube, for example. In this regard, at least one semiconductor layer 7 may be disposed on the surface of the body 6, or within the body 6. This may result in uniform generation of multidirectional light or luminance.

In another embodiment of the invention, the SLED in FIG. 4 may comprise more than one body 6 of solid geometry, thereby resulting in a cascaded SLED. The plurality of bodies may be coupled so that only a single pair of electrodes may be used. Alternatively, each of the plurality of bodies may utilize a separate pair of electrodes, so that a plurality of electrodes may be used to may be coupled so that the cascaded SLED may be powered when the plurality of electrodes is coupled to electricity. The lens 8 may be adapted to cover the plurality of bodies 6 so that a single cascaded SLED may be formed

Accordingly, aspects of the invention may be realized in hardware, software, firmware or a combination thereof. The invention may be realized in a centralized fashion in at least one computer system or in a distributed fashion where different elements are spread across several interconnected computer systems. Any kind of computer system or other apparatus adapted for carrying out the methods described herein is suited. A typical combination of hardware, software and firmware may be a general-purpose computer system with a computer program that, when being loaded and executed, controls the computer system such that it carries out the methods described herein.

One embodiment of the present invention may be implemented as a board level product, as a single chip, application specific integrated circuit (ASIC), or with varying levels integrated on a single chip with other portions of the system as separate components. The degree of integration of the system will primarily be determined by speed and cost considerations. Because of the sophisticated nature of modern processors, it is possible to utilize a commercially available processor, which may be implemented external to an ASIC implementation of the present system. Alternatively, if the processor is available as an ASIC core or logic block, then the commercially available processor may be implemented as part of an ASIC device with various functions implemented as firmware.

The present invention may also be embedded in a computer program product, which comprises all the features enabling the implementation of the methods described herein, and which when loaded in a computer system is able to carry out these methods. Computer program in the present context may mean, for example, any expression, in any language, code or notation, of a set of instructions intended to cause a system having an information processing capability to perform a particular function either directly or after either or both of the following: a) conversion to another language, code or notation; b) reproduction in a different material form. However, other meanings of computer program within the understanding of those skilled in the art are also contemplated by the present invention.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

1.-16. (canceled)

17. A super luminance light-emitting diode (SLED) comprising:
a light-emitting element of solid geometry comprising a p-n junction, said light emitting element of solid geometry enables distribution of light energy that is multidirectional;
at least one pair of electrodes for coupling said light-emitting element of solid geometry to a source of electricity; and
a lens of solid geometry enclosing said light-emitting element and at least a portion of said at least one pair of electrodes,
wherein said light-emitting element emits light from substantially the entire surface of said light-emitting element of solid geometry.

18. The SLED of claim 17, wherein said light-emitting element of solid geometry is a sphere.

19. The SLED of claim 7, wherein said light-emitting element of solid geometry is a cube.

20. The SLED of claim 17, wherein said p-n junction comprises at least one semiconductor layer disposed on a surface of said light-emitting element of solid geometry.

21. The SLED of claim 17, wherein said p-n junction comprises at least one semiconductor layer disposed within a body of said light-emitting element of solid geometry.

22. The SLED of claim 17, wherein said lens comprises an outer surface external to said light-emitting element and an inner surface proximate to said light-emitting element.

23. The SLED of claim 22, wherein said lens comprises a filter that filters said distributed light energy, and wherein said filter is disposed on at least one of the following: said outer surface and said inner surface of said lens.

24. The SLED of claim 17, wherein said lens magnifies said multidirectional light energy distributed by said light emitting element.

25. A super luminance light-emitting diode (SLED) comprising a plurality of light-emitting elements of solid geometry, wherein each of said plurality of light-emitting elements of solid geometry comprises a p-n junction, and wherein at least a first of said plurality of light-emitting elements is operatively coupled to at least a second of said plurality of light-emitting elements, and wherein said plurality of light-emitting elements emit light from substantially the entire surface of said plurality of light-emitting elements of solid geometry.

26. The SLED of claim 25, further comprising a single pair of electrodes for coupling said plurality of light-emitting elements of solid geometry to a source of electricity; and
a lens of solid geometry enclosing said plurality of light-emitting elements and at least a portion of said single pair of electrodes.

27. The SLED of claim 25, further comprising at least one pair of electrodes for coupling said plurality of light-emitting elements of solid geometry to a source of electricity; and
a lens of solid geometry enclosing said plurality of light-emitting elements and at least a portion of said at least one pair of electrodes.

28. The SLED of claim 27, wherein each of said plurality of light emitting elements of solid geometry enables distribution of light energy that is multidirectional.

29. The SLED of claim 27, wherein each of said plurality of light-emitting elements comprises at least one of the following: a sphere and a cube.

30. The SLED of claim 27, wherein said p-n junction for each of said plurality of light-emitting elements comprises at least one semiconductor layer disposed on a surface of said each of said plurality of light-emitting elements of solid geometry.

31. The SLED of claim 27, wherein said p-n junction for each of said plurality of light-emitting elements comprises at least one semiconductor layer disposed within a body of said each of said plurality of light-emitting elements of solid geometry.

32. The SLED of claim 27, wherein said lens comprises a filter that filters said distributed light energy, and wherein said filter is disposed on at least one of the following: an outer surface of said lens and an inner surface of said lens.

33. The SLED of claim 27, wherein said lens magnifies said multidirectional light energy distributed by said plurality of light emitting elements.
